(19) United States
(12) Patent Application Publication
(10) Pub. No.: US 2025/0372148 A1
(43) Pub. Date: Dec. 4, 2025

(54) APPARATUSES, SYSTEMS, AND METHODS FOR DQS DOMAIN ROUTING OF DATA TO BANK LOGIC

(71) Applicant: Micron Technology, Inc., Boise, ID (US)

(72) Inventors: Ping Na Li, Plano, TX (US); Parthasarathy Gajapathy, Mckinney, TX (US)

(73) Assignee: Micron Technology, Inc., Boise, ID (US)

(21) Appl. No.: 19/196,498

(22) Filed: May 1, 2025

Related U.S. Application Data
(60) Provisional application No. 63/652,289, filed on May 28, 2024.

(51) Int. Cl. G11C 11/4076; G11C 11/408

(52) U.S. Cl. CPC G11C 11/4076; G11C 11/4087

(57) ABSTRACT

A memory device receives a bank address in a clock domain and data in a data strobe (DQS) domain. The bank address is shifted into the DQS domain and the shifted bank address is used to route the data to a bank group logic region. In this way, the data remains in the DQS domain until it enters the bank group logic region. This may allow for relaxed timing requirements compared to shifting the data into the clock domain before routing it to the bank group logic region.

### CROSS REFERENCE TO RELATED APPLICATION(S)

This application claims the benefit under 35 U.S.C. § 119 of the earlier filing date of U.S. Provisional Application Ser. No. 63/652,289 filed May 28, 2024 the entire contents of which is hereby incorporated by reference in its entirety for any purpose.

### BACKGROUND

Information may be stored on memory cells of a memory device. The memory cells may be organized at the intersection of word lines (rows) and bit lines (columns). During access operations, the memory accesses information in the memory cells for example to write new information to those memory cells as part of a write operation or to read information from the memory cells as part of a read operation.

The memory may time operations based on a clock signal. However, during access operations, data may be sent or received through data terminals of the memory with timing based on a data strobe signal. Accordingly, during access operations, the data may need to cross between a clock domain, where the timing of various operations is controlled by the clock signal and a data strobe domain, where the timing of operations is controlled by the data strobe signal. It may be useful to select where the crossing occurs in order to manage timing of various operations within the memory.

### BRIEF DESCRIPTION OF THE DRAWINGS

FIG. 1 is a block diagram of a memory system according to some embodiments of the present disclosure.

FIG. 2 shows a block diagram of a layout of a portion of a memory device according to some embodiments of the present disclosure.

FIG. 3 is a schematic diagram of clock domain to data strobe domain crossover logic according to some embodiments of the present disclosure.

FIG. 4 is a timing diagram of example write operations in a memory device according to some embodiments of the present disclosure.

FIG. 5 is a flow chat of a method of providing write data to a bank group logic region in a DQS domain according to some embodiments of the present disclosure.

### DETAILED DESCRIPTION

The following description of certain embodiments is merely exemplary in nature and is in no way intended to limit the scope of the disclosure or its applications or uses. In the following detailed description of embodiments of the present systems and methods, reference is made to the accompanying drawings which form a part hereof, and which are shown by way of illustration specific embodiments in which the described systems and methods may be practiced. These embodiments are described in sufficient detail to enable those skilled in the art to practice presently disclosed systems and methods, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

Information in a memory array may be accessed by one or more access operations, such as read or write operations. During an example access operation a word line may be activated (or opened) based on a row address and then selected memory cells along that active word line may have their information read or written to based on which bit lines are accessed, which may be based on a column address. When the access operation is over, the word line may be pre-charged to inactivate (or close) the word line.

During an access operation, data is sent and received along data (DQ) terminals. The data is timed based on a data strobe (DQS) signal, a periodic clock signal. The rising (and/or falling) edges of the DQS signal are used to determine when to latch the voltage on the DQ terminal as a bit of information. Circuits and signals which are operated based on the timing of the DQS signal may generally be referred to as being part of a DQS domain.

The memory also has a clock signal which is used to control other circuits and operations which are part of a clock domain. The clock signal may be received and various internal clock signals may be generated from that clock signal. Circuits and signals which are operated based on the timing of the clock signal or signals derived therefrom may generally be referred to as part of the clock domain. The operation of most of the memory's internal circuits may be part of the clock domain.

During a write operation, data is received at the DQ terminals as part of the DQS domain. The commands and addresses related to the write operation are received at command/address terminals as part of the clock domain. The addresses include a bank address which specifies which bank (or bank group) of the memory the data should be routed to. In a conventional memory device, the data may be shifted into the clock domain when the bank address is used to route the data to the specified bank logic. For example, a multiplexer may receive the data (still in the DQS domain) and route the data based on the bank address (in the clock domain), and this routing shifts the data into the clock domain. However, this may cause a number of potential problems. For example, in order to prevent misalignment between the data and the bank address, the timing requirements between the DQS and the addresses may be extremely tight. Similarly the timing of commands may be relatively strict.

The present disclosure is drawn to apparatuses, systems, and methods for DQS domain routing of data to bank logic. The memory device shifts the bank address (or signals derived therefrom) into the DQS domain. The routing of the data to the bank logic specified by the bank address is thus performed in the DQS domain, and the data remains in the DQS domain until it enters the bank logic. This allows for an extended timing window tolerance of the data and commands, and also an increased tolerance for misalignment between DQS and the clock signal. For example, commands may use the tCCD_L_WR2 timing specification, since the data reaches the bank still in the DQS domain before transitioning to the clock domain.

In an example implementation, the memory receives a write command and a bank address at command/address terminals in the clock domain. Based on the write command, a write state signal and a bank group address are generated, both in the clock domain. The write state signal is used to signal the DQS terminals to begin receiving DQS, which in turn causes the data to begin being received at the DQ terminals in the DQS domain. The write start signal is also provided to a register, such as a FIFO, which clocks input of the bank address bits based on the write start signal. The DQS signal is also provided to the register, which clocks the output of the bank group address using the DQS signal. The bank group address is now in the DQS domain, and is decoded into a sample signal, which is provided to a multiplexer. The multiplexer routes the data to bank logic based on the value of the sample signal. In this way, the routing of the data to the bank logic remains in the DQS domain, and the data doesn't cross over to the clock domain until it enters the bank logic.

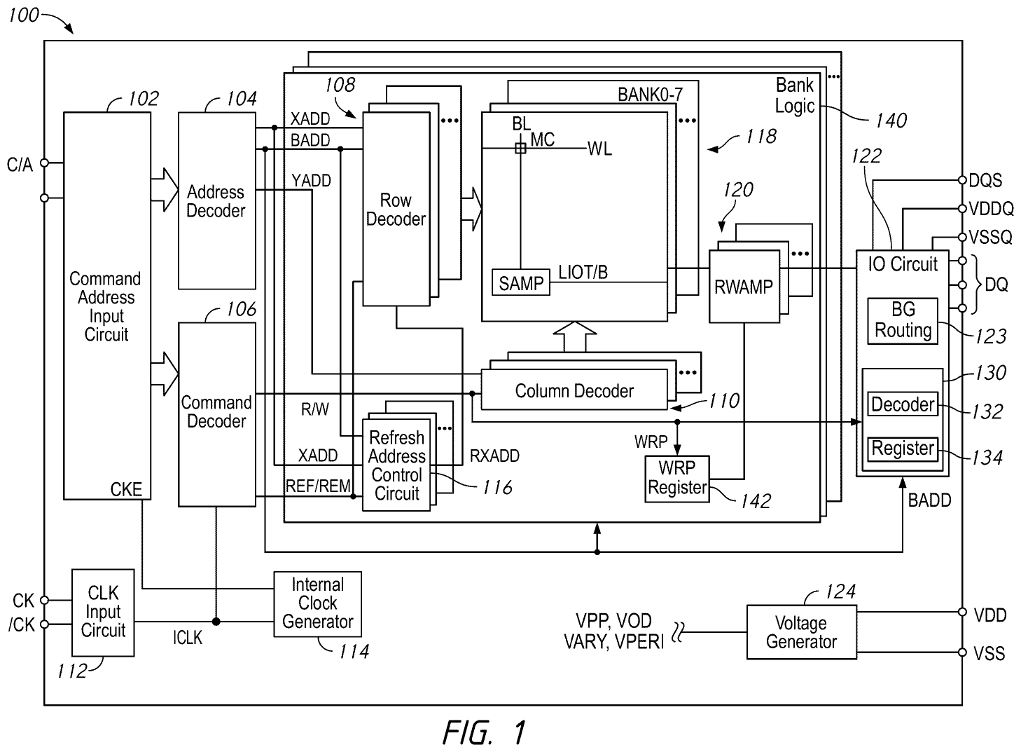

FIG. 1 is a block diagram of a semiconductor device according to at least one embodiment of the disclosure. The semiconductor device 100 may be a semiconductor memory device, such as a DRAM device integrated on a single semiconductor chip. The device 100 may be operated by a controller. The memory receives various commands, data, signals, and voltages (e.g., from the controller).

The semiconductor device 100 includes a memory array 118. The memory array 118 is shown as including a plurality of memory banks. In the embodiment of FIG. 1, the memory array 118 is shown as including N+1 memory banks BANK0-BANKN. For example, there may be four, eight, or sixteen banks. More or fewer banks may be used in other example embodiments. Each memory bank includes a plurality of word lines WL (rows), a plurality of bit lines BL (columns), and a plurality of memory cells MC arranged at intersections of the plurality of word lines WL and the plurality of bit lines BL. Each memory cell stores information. For example, the memory cell may be a capacitive element which stores a bit of information as an amount of charge on the capacitive element.

The memory banks may each be associated with a set of bank logic circuits, here shown as being part of bank logic 140. The bank logic circuits may be located in a bank logic region of the memory device 100 which is physically close to the associated bank. For example, the first bank may have a first bank logic region and first set of bank logic circuits, the second bank may have a second bank logic region and second set of bank logic circuits, and so forth. The bank logic circuits may be repeated on a bank-by-bank basis. In some embodiments, banks may be grouped together into bank groups. The banks within a bank group may share one or more components of the bank logic 140. In the example of FIG. 1, the bank logic 140 is shown containing certain circuits such as the row decoder 108, column decoder 110, refresh control circuit 116, and read/write amplifiers 120. Other example embodiments may include different arrangements of which circuits are part of the bank logic 140.

The selection of the word line WL is performed by a row decoder 108 and the selection of the bit lines BL is performed by a column decoder 110. In the embodiment of FIG. 1, the row decoder 108 includes a respective row decoder for each memory bank and the column decoder 110 includes a respective column decoder for each memory bank. The bit lines BL are coupled to a respective sense amplifier (SAMP). Read data from the bit line BL is amplified by the sense amplifier SAMP, and transferred to read/write amplifiers 120 over local data lines (LIO) and global data lines (GIO). Conversely, write data outputted from the read/write amplifiers 120 is transferred to the sense amplifier SAMP over the GIO and LIO and amplified by the SAMP over the BL to the memory cell at the intersection with the active bit line.

The semiconductor device 100 may employ a plurality of external terminals. The external terminals include command and address (C/A) terminals along a command and address bus to receive commands and addresses. Other external terminals include clock terminals to receive clocks CK and/CK along a clock bus, data terminals DQ to send and receive data along a data bus, and power supply terminals to receive power supply potentials such as VDD, VSS, VDDQ, and VSSQ. The memory device 100 also includes data strobe (DQS) terminals which are used to receive a DQS signal. The DQS signal is used by an input/output (IO) circuit 122 to clock data as it is being sent or received along the DQ terminals.

The clock terminals are supplied with external clocks CK and/CK that are provided to an input circuit 112. The external clocks may be complementary. The input circuit 112 generates an internal clock ICLK based on the CK and/CK clocks. The ICLK clock is provided to the command decoder 110 and address decoder 108 and to an internal clock generator 114. The internal clock generator 114 provides various internal clocks LCLK based on the ICLK clock. The LCLK clocks may be used for timing operation of various internal circuits. For example, the clock signal LCLK may be a divided clock signal which is half the frequency of the external clocks CK and/CK. One or more clock signals ICLK and LCLK may be used by the circuits of the bank logic 140 to time the operation thereof.

The C/A terminals may be supplied with memory addresses. The memory addresses supplied to the C/A terminals are transferred, via a command/address input circuit 102, to an address decoder 104. The address decoder 104 receives the address and supplies a decoded row address XADD to the row decoder 108 and supplies a decoded column address YADD to the column decoder 110. The address decoder 104 may also supply a decoded bank address BADD, which may indicate the bank of the memory array 118 containing the decoded row address XADD and column address YADD. The C/A terminals may be supplied with commands. Examples of commands include timing commands for controlling the timing of various operations, access commands for accessing the memory, such as read commands for performing read operations and write commands for performing write operations, as well as other commands and operations. The access commands may be associated with one or more row address XADD, column address YADD, and bank address BADD to indicate the memory cell(s) to be accessed.

The commands may be provided as internal command signals to a command decoder 106 via the command/address input circuit 102. The command decoder 106 includes circuits to decode the internal command signals to generate various internal signals and commands for performing operations. For example, the command decoder 106 may provide a row command signal to select a word line and a column command signal to select a bit line. The command decoder 106 and address decoder 104 may be operated in a clock domain based on ICLK.

As part of an example read operation, the device 100 may receive a read command along with memory addresses which indicate where the read command should be performed. Responsive to internal commands (such as a row activate command ACT) issued by the command decoder 106, the word line selected by XADD is activated by the row decoder 108 and the data on the memory cells along that word line is amplified onto the intersecting bit lines by sense amplifiers (SAMP). Responsive to internal commands and the column address YADD, the column decoder 110 couples selected bit lines through local and global input/output lines (LIO and GIO) to the read/write amplifiers 120. The read/write amplifiers 120 provide the data to the IO circuit 122, which provides the data along one or more DQ terminals. The data may be provided in synchronization with a data strobe clock DQS.

As part of an example write operation, the device 100 may receive a write command along with memory addresses which indicate where the write command should be performed. Responsive to internal commands (such as a row activate command ACT) issued by the command decoder 106, the word line selected by XADD is activated by the row decoder 108 and the data on the memory cells along that word line is amplified onto the intersecting bit lines by sense amplifiers (SAMP). Responsive to internal commands and the column address YADD, the column decoder 110 couples selected bit lines through local and global input/output lines (LIO and GIO) to the read/write amplifiers 120. The IO circuit 122 receives data along the DQ terminals in synchronization with the DQS signal, and provides the data to the bank logic 140 specified by a bank address. The read write amplifiers 120 in the specified bank logic provide the data along the LIO/GIO to the selected bit lines where it is written to the memory cells at the intersections with the active word line.

During write operations, the IO circuit 122 receives the data in the DQS domain and routes the data to the appropriate bank logic 140 using operations controlled by the DQS domain. The address decoder 104 provides a bank address BADD which specifies which bank logic 140 the data is intended for. The address decoder 104 operates in a clock domain. The IO circuit 122 includes a bank group routing signal generator circuit 130. The bank group routing signal generator circuit 130 receives the bank address BADD in the CLK domain and provides a decoded bank group routing signal in the DQS domain. The IO circuit 122 includes a bank group routing circuit 122 which receives the data and sends the data to a bank logic 140 region based on the decoded bank group routing signal. Since the data and the decoded bank group routing signal are both in the DQS domain, the data remains in the DQS domain until it enters the bank logic 140.

The bank group routing signal generator circuit 130 includes a register 134. For example, the register 134 may operate as a first in first out (FIFO) register. The input of the register 134 may be clocked to a signal in the clock domain, such as a write command signal. The output of the register 134 may be clocked to a signal in the DQS domain. The register 130 inputs the bank address BADD, or a portion thereof, and provides it synchronized to the DQS domain. The bank group routing signal generator circuit 130 also includes a decoder 132 which decodes the DQS synchronized bank address into the bank group routing signal.

The memory device 100 also includes a WRP register 142. The WRP register 142 is used as part of WRP operations. During a WRP operation, WRP write data stored in the WRP register 142 is written to the array 118. For example, the memory 100 may receive a WRP command and addresses, however instead of receiving data over the DQ terminals, the WRP write data stored in the WRP register 142 of the bank specified by the bank address is written instead. Since the data comes from a register and not along the DQ terminals, a DQS signal is not provided. Accordingly, the write operation may be wholly in the clock domain. The WRP register 142 may thus be located in the bank logic 140, to place it ‘downstream’ of where DQS would normally be used for bank routing by the IO circuit 122. The controller may write the WRP write data to the WRP register 142, in order to more quickly allow writing of commonly used sets of data.

The device 100 may also receive commands causing it to carry out refresh operations. A refresh control circuit 116 may generate refresh address RXADD and the row decoder may refresh the word lines associated with that refresh address RXADD. The memory device 100 may receive a refresh signal REF and perform one or more refresh operations responsive to the refresh signal. In some embodiments, the refresh control circuit 116 may perform different types of refresh operations. For example, the refresh control circuit 116 may perform ‘normal’ refresh operations where the refresh address RXADD is generated using sequence logic, for example to count through the row addresses or the refresh control circuit 116 may perform targeted refresh operations on specific addresses (e.g., the victims of an identified aggressor).

The power supply terminals are supplied with power supply potentials VDD and VSS. The power supply potentials VDD and VSS are supplied to an internal voltage generator circuit 124. The internal voltage generator circuit 124 generates various internal potentials VPP, VARY, VPERI, and the like based on the power supply potentials VDD and VSS supplied to the power supply terminals. The internal potential VPP is mainly used in the row decoder 108, the internal potentials VARY are mainly used in the sense amplifiers SAMP included in the memory array 118, and the internal potential VPERI is used in many peripheral circuit blocks.

The power supply terminals are also supplied with power supply potentials VDDQ and VSSQ. The power supply potentials VDDQ and VSSQ are supplied to the input/output circuit 122. The power supply potentials VDDQ and VSSQ supplied to the power supply terminals may be the same potentials as the power supply potentials VDD and VSS supplied to the power supply terminals in an embodiment of the disclosure. The power supply potentials VDDQ and VSSQ supplied to the power supply terminals may be different potentials from the power supply potentials VDD and VSS supplied to the power supply terminals in another embodiment of the disclosure. The power supply potentials VDDQ and VSSQ supplied to the power supply terminals are used for the input/output circuit 122 so that power supply noise generated by the input/output circuit 122 does not propagate to the other circuit blocks.

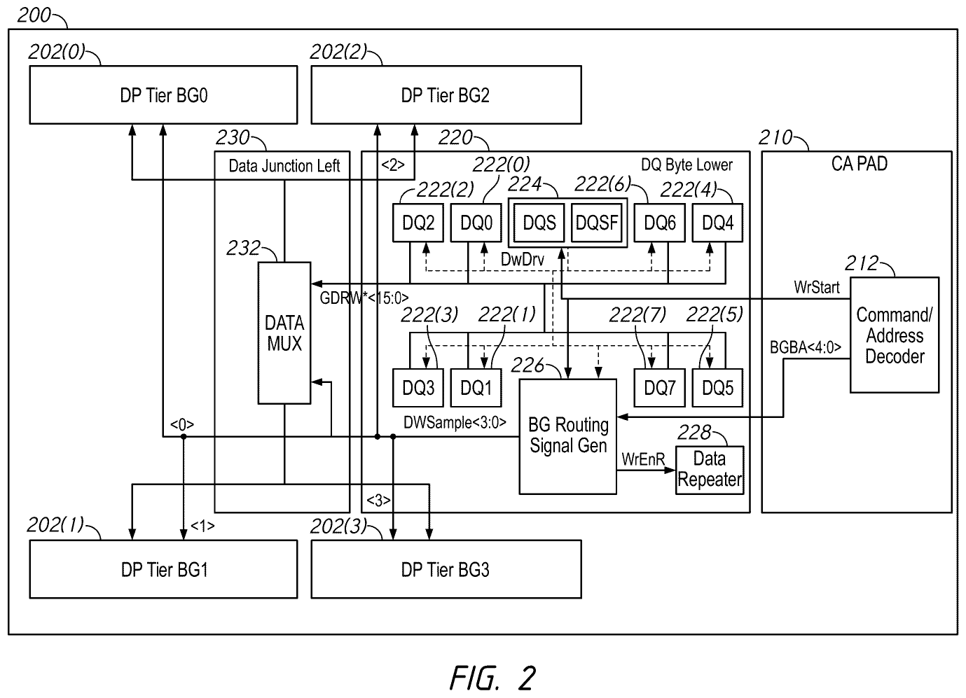

FIG. 2 shows a block diagram of a layout of a portion of a memory device according to some embodiments of the present disclosure. The memory device 200 may, in some embodiments, represent a portion of the memory device 100 of FIG. 1. For the sake of brevity, certain signals, circuits, and operations already described with respect to FIG. 1 are not shown or described again with respect to FIG. 2.

The memory device 200 includes a central logic region which includes a CA pad region 210, a lower DQ byte region 220, and a left data junction region 230. The memory device 200 also includes four bank group logic regions 202(0) to 202(3) (e.g., bank logic 140 of FIG. 1). In some embodiments, the memory device 200 may also include an upper DQ byte region and a right data junction region as well as additional bank group logic regions, for example extending to the right of the CA pad region 210. However, since those regions may be symmetric with the respective lower DQ byte region 220, left data junction region 230, and bank group logic regions 202, and generally include analogous components and functions to the described regions, only one side of the memory device 200 is described herein.

The CA Pad region 210 is coupled to the command/address bus to receive command address signals. For example, during a write operation, the CA pad region 210 may receive a row, column, and bank address and a write command. The CA pad region 210 includes a command address decoder 212. In the view of FIG. 2, the command decoder (e.g., 106 of FIG. 1) and address decoder (e.g., 104) are shown as a single box 212. During an example write operation, the command/address decoder 212 receives signals along the command/address bus which it decodes into a write state signal WrStart based on a write command a bank group address BGBA based on a bank address. The bank group address BGBA may be a subset of the bits of the bank address BADD of FIG. 1. The command address decoder 212 may operate as part of a clock domain.

The memory device includes a lower DQ byte region 220 which includes 8 DQ terminals 222(0) to 222(7) and DQS terminals 224. Responsive to the write start signal WrStart, indicating the beginning of a write operation, the DQS terminals 224 will begin receiving the data strobe signal DQS (and its compliment DQSF). The DQS signal is used to generate a write driver signal DwDrv, which is provided to the DQ terminals 222. Responsive to the write driver signal DwDrv, the data terminals begin receiving data. Parallelizer circuits coupled to the DQ terminals 222 shift the data received in serial fashion along each DQ terminal 222 into parallel write data GDRW.

The lower DQ byte region 220 includes a bank group routing signal generator circuit 226 (e.g., 130 of FIG. 1). The bank group routing signal generator circuit 226 shifts the bank group address BGBA into the DQS domain and provides a decoded bank group routing signal DWSample in the DQS domain. The bank group routing signal generator includes a register which clocks the input of the bank group address BGBA based on the write start signal WrStart, but clocks the output based on DwDrv.

The left data junction region 230 includes a multiplexer circuit 232, which receives the parallelized write data GDRW and directs it to one of the bank group regions 202 based on a value of the bank group routing signal DWSample. In this manner, the circuits of the lower byte region 220 and the left data junction region 230 may operate in the DQS domain, while the circuits of the bank group regions 202 and CA pad region 210 may operate in the clock domain.

In some embodiments, the memory device 202 may receive a bank address BGBA which indicates that the data received in the lower byte 220 is intended to for bank groups associated with a right data junction (not shown). If the bank address BGBA indicates the data received at the lower byte 220 is intended for the right data junction, the bank group routing signal generator provides a right write enable signal WrEnR. A data repeater circuit 228 provides the data GDRW to the right data junction responsive to WrEnR. Similarly, although not shown in FIG. 2, an upper byte may receive data intended for the left data junction 230, in which case a data repeater of the upper byte may provide the data to the multiplexer 232.

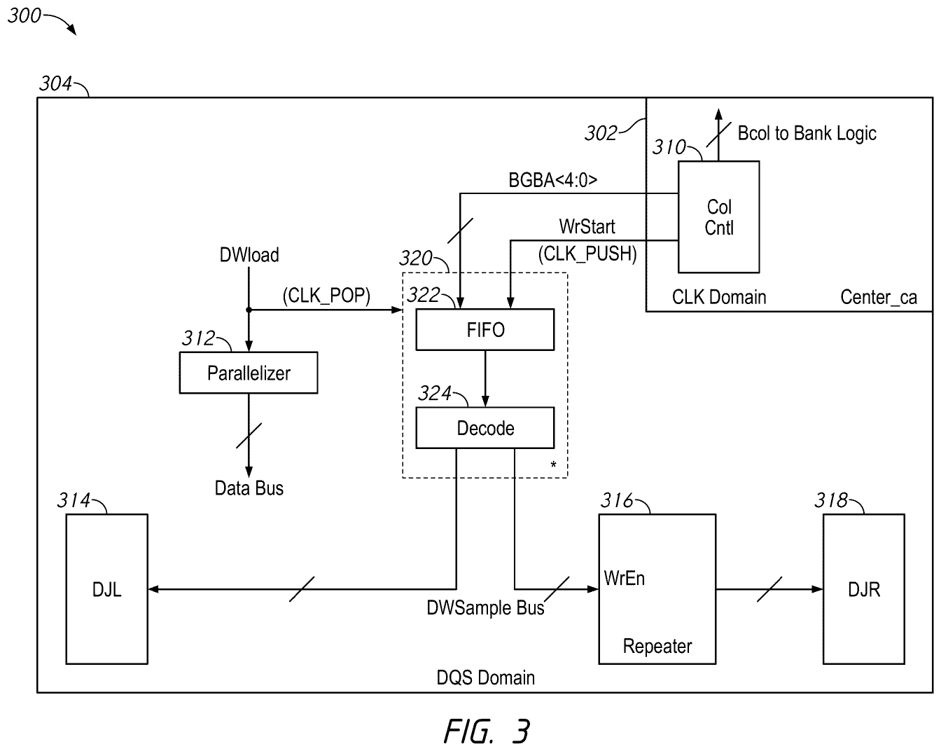

FIG. 3 is a schematic diagram of clock domain to data strobe domain crossover logic according to some embodiments of the present disclosure. The crossover logic 300 of FIG. 3 may, in some embodiments, implement a portion of a memory device such as 100 of FIG. 1, 200 of FIG. 2, or combinations thereof. The crossover logic 300 shows certain components and signals used to shift the bank address information into a DQS domain so that the data can be directed to the bank logic within the DQS domain. The crossover logic 300 includes a box 302 which shows circuits which operate in the clock domain and a box 304 which shows circuits which operate in the DQS domain.

The box 302 shows a control circuit 310 such as a command/address decoder (e.g., 106/104 of FIG. 1, 212 of FIG. 2, or combinations thereof). Based on signals received along a command/address bus, the control circuit 310 provides a write start signal WrStart (e.g., responsive to a write command) and a bank group address BGBA (e.g., responsive to a bank address). Since the control circuit 310 is operated in the clock domain, the signals WrStart and BGBA are provided with timing based on the clock domain.

The box 304 shows a parallelizer circuit 312, a bank group routing signal generator circuit 320 (e.g., 130 of FIGS. 1 and/or 226 of FIG. 2), a data repeater circuit 316 (e.g., 228 of FIG. 2), a left data junction 314 (e.g., 230 of FIG. 2), and a right data junction 318, all of which operate with timing based on the DQS domain. The parallelizer circuit 312 may be associated with a DQ circuit (not shown in FIG. 2) such as 222 of FIG. 2. For ease of explanation, only a single parallelizer circuit is shown and described with respect to FIG. 3, however there may be a parallelizer circuit for each DQ terminal in some embodiments.

The parallelizer circuit 312 operates with timing based on a load signal DWload, which is derived from a write data driver signal such as DwDrv. The loading signal DWload may operate with timing based on DQS, and may be associated with the DQ terminal that the parallelizer circuit 312 is associated with. The parallelizer circuit 312 takes serial data from the DQ terminal and puts it in to parallel along a data bus.

The bank group routing signal generator circuit 320 includes a FIFO register 322 (e.g., 134 of FIG. 1) coupled to the bank group address BGBA as an input, the write start signal WrStart as a clock push signal CLK_PUSH and the load signal DWload as a clock pop signal CLK_POP. Responsive to the clock push signal WrStart, the bank address BGBA is loaded into the latch circuits of the FIFO register 322. Responsive to the clock pop signal DWload the bank address BGBA stored in the latch circuits are read out of the FIFO register 322 to a decoder circuit 324 (e.g., 132 of FIG. 1). The FIFO register takes the BGBA as an input in the clock domain and provides it as an output in the DQS domain.

The decoder circuit 324 uses the bank group address BGBA to generate the bank group routing signal and provide it along a DWSample bus. If the bank group address indicates the left data junction 314, the bank group routing signal is provided directly to the junction. If the bank group address indicates the right data junction 318, the bank group routing signal is provided through a data repeater 316 to the right data junction 318.

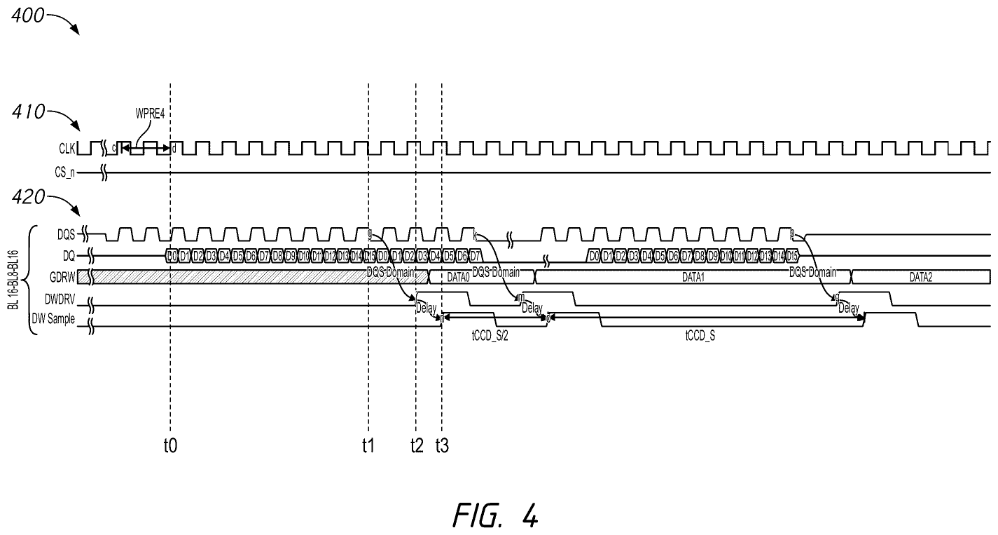

FIG. 4 is a timing diagram of example write operations in a memory device according to some embodiments of the present disclosure. The timing diagram 400 may, in some embodiments, represent operations of a memory device such as 100 of FIG. 1, 200 of FIG. 2, crossover logic 300 of FIG. 3, or combinations thereof. The timing diagram 400 shows a clock signal CLK as part of a clock domain 410. The timing diagram 400 also shows a DQS domain 420 which shows a DQS signal, data along the DQ terminals, parallelized data GDRW, a write driver signal DWDRV and a bank group routing signal DWSample.

The timing diagram 400 shows an example sequence of write operations. A write operation with a burst length of 16 (e.g., 16 serial bits along each DQ terminal), a write operation with a burst length of 8, and another write operation with a burst length of 16. At an initial time to, the data starts being received along the data terminal and is latched in synchronization with the DQS signal. At a time t1, the final bit of the burst is latched (e.g., data bit D15). This causes the activation of the driver signal DWDRV a delay time later at t2. A second delay time after t2, the routing signal is activated along DWSample at t3.

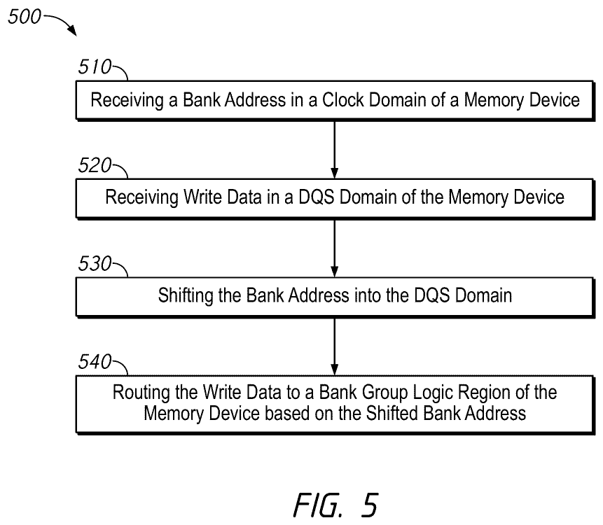

FIG. 5 is a flow chat of a method of providing write data to a bank group logic region in a DQS domain according to some embodiments of the present disclosure. The method 500 may, in some embodiments, be implemented by one or more of the apparatuses or systems described herein. For example, the method 500 may be implemented by the memory device 100 of FIG. 1, 200 of FIG. 2, the crossover logic 300 of FIG. 3, or combinations thereof.

The method 500 may generally begin with box 510, which describes receiving a bank address in a clock domain of a memory device. For example, the method 500 may include receiving the bank address along command/address terminals, and decoding the bank address with an address decoder circuit (e.g., 104 of FIG. 1, 212 of FIG. 2, and/or 310 of FIG. 3). The bank address may include a bank group address. The method 500 may include receiving a clock signal and controlling the operation of the address decoder circuit with the clock signal, one or more signals derived therefrom, or combinations thereof.

Box 510 is generally followed by box 520, which describes receiving write data in a DQS domain of the memory device. For example, the method 500 may include receiving a DQS signal along DQS terminals (e.g., 224 of FIG. 2) of the memory device and controlling the receipt of the write data based on the DQS signal, one or more signals derived therefrom, or combinations therefrom.

Box 520 is generally followed by box 530, which describes shifting the bank address into the DQS domain. For example, the method 500 may include shifting the bank address with a register (e.g., 134 of FIGS. 1 and/or 322 of FIG. 3) of a bank group routing signal generator circuit (e.g., 130 of FIG. 1, 226 of FIG. 2, and/or 320 of FIG. 3). The method 500 may include loading the bank address into the register based on a signal in the clock domain and unloading the register for example by providing the bank address from the register based on a signal in the DQS domain. For example the method 500 may include generating a write start signal based on write command, loading the bank address into the register based on the write start signal, generating a write data driver signal in the DQS domain, and providing the shifted bank address from the register based on the write driver signal. The method 500 may also include receiving the DQS signal responsive to the write start signal, receiving the write data at data terminals with timing based on the DQS signal and parallelizing the write data (e.g., with parallelizer circuits such as 312 of FIG. 3) with timing based on the write data driver signal.

Box 530 is generally followed by box 540, which describes routing the write data to a bank group logic region of the memory device based on the shifted bank address. For example, the method 500 may include decoding the shifted bank address into a bank group routing signal and routing the write data with a multiplexer circuit based on the bank group routing signal. The method 500 may include writing the data to the memory bank within the bank logic region. The writing of the data to the memory bank may be performed in the clock domain. The method 500 may include keeping the write data in the DQS domain until it enters the bank group logic region. The method 500 may include crossing the write data from the DQS domain to the clock domain within the bank group logic region.

The method 500 may include receiving a WRP command and writing WRP write data from a WRP register to a memory bank in the clock domain. The WRP register is located the bank group logic region.

It is to be appreciated that any one of the examples, embodiments or processes described herein may be combined with one or more other examples, embodiments and/or processes or be separated and/or performed amongst separate devices or device portions in accordance with the present systems, devices and methods.

Finally, the above-discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. An apparatus comprising:
a plurality of bank group logic regions of a memory device;
an address decoder circuit configured to provide a bank address in a clock domain of the memory device;
a bank group routing signal generator circuit configured to shift the bank address into a data strobe (DQS) domain of the memory device and provide a bank group routing signal in the DQS domain based on the shifted bank address;
a data terminal configured to receive write data in the DQS domain; and
a bank group routing circuit configured to provide the write data to a selected one of the plurality of bank group logic regions based on the bank group routing signal.

2. The apparatus of claim 1, wherein the bank group routing signal generator circuit includes a register configured to shift the bank address into the DQS domain.

3. The apparatus of claim 2, wherein the register is configured to load the bank address based on a first signal in the clock domain and configured to provide the shifted bank address based on a second signal in the DQS domain.

4. The apparatus of claim 2, wherein the bank group routing signal generator circuit further includes a decoder configured to generate the bank group routing signal based on the shifted bank address.

5. The apparatus of claim 1, wherein the bank group routing circuit comprises a multiplexer configured to receive the write data and provide the write data to the selected one of the plurality of bank group logic regions based on a state of the bank group routing signal.

6. The apparatus of claim 1, wherein the write data remains in the DQS domain until it enters the selected one of the bank group logic regions.

7. The apparatus of claim 1, further comprising:
a command decoder circuit configured to provide a write start signal in the clock domain responsive to a write command;
DQS terminals configured to provide a data driver signal in the DQS domain responsive to the write start signal,
wherein the data terminals are configured to provide the write data responsive to the data driver signal.

8. The apparatus of claim 1, wherein the plurality of bank group logic regions each include a respective one of a plurality of WRP registers each configured to store WRP write data, and wherein one or more selected ones of the plurality of WRP registers is configured to provide the stored WRP write data in the clock domain as part of a WRP operation.

9. The apparatus of claim 1, wherein the bank group routing circuit is located in a data junction region, and the bank group routing signal generator circuit is located in a data terminal byte region.

10. A method comprising:
receiving a bank address in a clock domain of a memory device;
receiving write data in a data strobe (DQS) domain of the memory device;
shifting the bank address into the DQS domain; and
routing the write data to a bank group logic region of the memory device based on the shifted bank address.

11. The method of claim 10, further comprising keeping the data in the DQS domain until it enters the bank group logic region.

12. The method of claim 10, further comprising:
generating a write start signal in the clock domain;
loading the bank address into a register based on the write start signal;
generating a write data driver signal in the DQS domain; and
providing the shifted bank address from the register based on the write driver signal.

13. The method of claim 12, further comprising:
receiving a DQS signal responsive to the write start signal;
receiving the write data at one or more data terminals with timing based on the DQS signal; and
parallelizing the write data responsive to a write data driver signal.

14. The method of claim 10, further comprising:
decoding the shifted bank address into a bank group routing signal; and
routing the write data with a multiplexer circuit based on the bank group routing signal.

15. The method of claim 10, further comprising writing the data to a memory bank in the bank group logic region in the clock domain.

16. The method of claim 10, further comprising:
receiving a WRP command; and
writing WRP write data from a WRP register to a memory bank in the clock domain, wherein the WRP register is in the bank group logic region.

17. An apparatus comprising:
a command/address pad region configured to provide a write start signal and a bank group address in a clock domain;
a FIFO register configured to load the bank group address responsive to the write start signal and provide a shifted bank group address responsive to a write driver signal in the data strobe (DQS) domain; and
a decoder circuit configured to generate a bank group routing signal based on the shifted bank group address.

18. The apparatus of claim 17, further comprising:
a plurality of bank group logic regions; and
a multiplexer configured to direct write data to a selected one of the plurality of bank group logic regions.

19. The apparatus of claim 17, further comprising:
DQS terminals configured to begin receiving a DQS signal responsive to the write start signal;
data terminals configured to receive write data synchronized to the DQS signal; and
parallelizer circuits configured to parallelize the write data responsive to the write driver signal.

20. The apparatus of claim 17, further comprising:
a first data junction and a second data junction; and
a data repeater circuit configured to provide the bank group routing signal to one of the first junction and the second data junction.

21. The apparatus of claim 17, further comprising a plurality of bank group logic regions, wherein the bank group routing signal indicates a selected one of the bank group logic regions.
